(19) United States
(12) Patent Application Publication
(10) Pub. No.: US 2024/0002286 A1
(43) Pub. Date: Jan. 4, 2024

(54) COVER WINDOW, METHOD FOR MANUFACTURING THE COVER WINDOW, AND A DISPLAY DEVICE INCLUDING THE COVER WINDOW

(71) Applicant: Samsung Display Co., LTD., Yongin-si (KR)

(72) Inventors: Kyung-Man KIM, Yongin-si (KR); Byung Hoon KANG, Yongin-si (KR); Sang Hoon KIM, Yongin-si (KR); Sung Hoon KIM, Yongin-si (KR); Min-Hoon CHOI, Yongin-si (KR); Seong Jin HWANG, Yongin-si (KR)

(21) Appl. No.: 18/132,313

(22) Filed: Apr. 7, 2023

(30) Foreign Application Priority Data
Jun. 30, 2022 (KR) 10-2022-0080685

(51) Int. Cl. C03C 23/00; C03C 15/00; C03C 17/00; C03C 17/06; H05K 5/03

(52) U.S. Cl. CPC C03C 23/0025; C03C 15/00; C03C 17/002; C03C 17/06; H05K 5/03

(57) ABSTRACT

A manufacturing method of a cover window is provided. The method including: irradiating a laser at a plurality of first positions on a first surface of a glass, the laser having a focus value for each of the first positions; irradiating a laser at a plurality of second positions on a second surface of the glass, the laser having a focus value for each of the second positions; forming a curved portion on the first surface of the glass and a step portion on the second surface of the glass by etching the irradiated first and second positions of the glass; and forming a printed layer on the step portion in the second surface of the glass.

### CROSS-REFERENCE TO RELATED APPLICATION

This application claims priority to and the benefit of Korean Patent Application No. 10-2022-0080685, filed in the Korean Intellectual Property Office on Jun. 30, 2022, the entire content of which is incorporated herein by reference.

### BACKGROUND

### 1. Field

Aspects of embodiments of the present disclosure relate to a cover window, a method of manufacturing the cover window, and a display device including the cover window.

### 2. Description of the Related Art

Recently, various mobile electronic devices that include a liquid crystal display device or an organic light emitting diode display device, such as mobile phones, navigation devices, digital cameras, electronic books, portable game machines, or various terminals, etc., are being used.

In a conventional display device used in a mobile device, a transparent cover window is provided in front of a display panel so that a user can see a display unit. Because the cover window is at an outermost portion (e.g., forms an outermost surface) of the mobile device, it should be strong against external impact to protect the display panel and the like inside the device.

In addition, because a shape of the display device has varied in recent years, variously shaped the cover windows to be applied the display device are required.

The above information disclosed in this Background section is for enhancement of understanding of the background of the present disclosure, and therefore, it may contain information that does not form the prior art that is already known to a person of ordinary skill in the art.

### SUMMARY

Embodiments of the present disclosure provide a cover window having a desired curvature and a reduced (or minimized) step difference, a method of manufacturing the cover window, and a display device including the cover window.

According to an embodiment of the present disclosure, a manufacturing method of a cover window is provided. The method includes: irradiating a laser at a plurality of first positions on a first surface of a glass, the laser having a focus value for each of the first positions; irradiating a laser at a plurality of second positions on a second surface of the glass, the laser having a focus value for each of the second positions; forming a curved portion on the first surface of the glass and a step portion on the second surface of the glass by etching the irradiated first and second positions of the glass; and forming a printed layer on the step portion in the second surface of the glass.

The curved portion and the step portion may have a concavo-convex surface.

A line connecting of the second positions on the second surface of the glass may have same curvature as that of the curved portion of the glass.

During the irradiating of the laser at the plurality of first positions on the first surface of the glass, a hole may be formed in the first surface of the glass corresponding to each of the first positions.

A line connecting each of the holes may form a curved surface having a curvature in the first surface of the glass.

During the irradiating of the laser at the plurality of second positions on the second surface of the glass, the laser may be irradiated onto a region of the second surface of the glass.

A depth of the region irradiated with the laser may be in a range of about 1 μm to about 350 μm.

A width of the region irradiated with the laser may be in a range of about 0.1 mm to about 3 mm.

During the irradiating of the laser at the plurality of second positions on the second surface of the glass, the laser may be irradiated from an edge of the glass to pass through an entire thickness of the glass.

The region irradiated with the laser may be spaced apart from an edge of the glass.

The region irradiated with the laser may extend to an edge of the glass.

The forming of the printed layer on the step portion in the second surface of the glass may include: filling a printed layer material in the step portion; and planarizing the step portion filled with the printed layer material.

The printed layer may include a black material.

The manufacturing method may further include forming a transparent layer between the printed layer and the glass.

The manufacturing method may further include forming a metal layer between the printed layer and the glass.

A depth of the step portion may increase toward an edge of the glass, and a thickness of the printed layer may increase toward the edge of the glass.

A curved portion of the glass may be formed on the second surface of the glass.

A curvature of the curved portion on the first surface of the glass may have a different curvature than that of the curved portion positioned on the second surface of the glass.

According to another embodiment of the present disclosure, a cover window includes: a glass having a first surface and a second surface, a first surface of the glass having a curved portion having a certain curvature, the second surface of the glass having a step portion at where the glass is partially removed; and a printed layer within the step portion in the second surface of the glass. The curved portion and the step portion have a concavo-convex surface.

The cover window may further include a flat portion between curved portions at opposite edges of the glass.

The cover window may further include a curved portion on the second surface of the glass.

A curvature of the curved portion on the first surface of the glass may be different from a curvature of the curved portion positioned on the second surface of the glass.

The cover window may further include a transparent layer between the printed layer and the glass.

The cover window may further include a metal layer between the printed layer and the glass.

The step portion may be spaced apart from an edge of the glass.

A depth of the step portion may be in a range of about 1 μm to about 350 μm, and a width of the step portion may be in a range of about 0.1 mm to about 3 mm.

According to another embodiment of the present disclosure, a cover window includes: a display panel; and a cover window on a first surface of the display panel. The cover window includes: a glass having a first surface and a second surface, the first surface of the glass having a curved portion having a certain curvature, the second surface of the glass having a step portion at where the glass is partially removed; and a printed layer within the step portion on the second surface of the glass. The curved portion and the step portion have a concavo-convex surface.

According to embodiments of the present disclosure, a cover window having a desired curvature and a reduced (or minimized) step difference, a method of manufacturing the cover window, and a display device including the cover window are provided.

### BRIEF DESCRIPTION OF THE DRAWINGS

FIG. 1 is a flowchart illustrating steps of a method of manufacturing a cover window according to an embodiment.

FIG. 2 schematically illustrates a process in which a laser is irradiated to an upper portion of a glass.

FIG. 3 illustrates a cross-section of a glass in which a hole is formed by laser irradiation.

FIG. 4 illustrates a position of an irradiating laser according to Table 1.

FIG. 5 schematically illustrates a process in which a laser is irradiated to a lower portion of a glass.

FIG. 6 illustrates an area affected by laser-by-laser irradiation.

FIG. 7 illustrates a result of etching the glass shown in FIG. 6.

FIGS. 8 and 9 respectively illustrate a process of forming a printed layer.

FIGS. 10 to 13 illustrate enlarged views of the portion A in FIG. 9 according to other embodiments.

FIG. 14 illustrates a cover window manufactured according to an embodiment.

FIGS. 15 and 16 respectively illustrate a cover window according to other embodiments.

FIG. 17 illustrates a cross-sectional view of the cover window shown in FIG. 14 taken along the line XVII-XVII′.

FIG. 18 illustrates a cover glass in which a step portion is not included on a lower surface thereof.

FIG. 19 illustrates a cross-section corresponding to that shown in FIG. 17 according to another embodiment.

FIG. 20 illustrates a cross-section corresponding to that shown in FIG. 18 according to another embodiment.

FIG. 21 illustrates a cross-section corresponding to that shown in FIG. 19 according to another embodiment.

FIG. 22 is a photograph of a cover window manufactured according to an embodiment.

FIG. 23 is a photograph of a step portion of a cover window manufactured according to an embodiment.

FIG. 24 is a photograph of a cover winder in which both upper and lower surfaces thereof have a curvature.

FIG. 25 is an enlarged image showing a surface of a laser irradiation region of a cover window manufactured according to an embodiment.

FIG. 26 schematically illustrates a display device including a cover window according to an embodiment.

### DETAILED DESCRIPTION

The present disclosure will be described more fully hereinafter with reference to the accompanying drawings, in which embodiments of the present disclosure are shown. As those skilled in the art would realize, the described embodiments may be modified in various different ways, all without departing from the spirit or scope of the present disclosure.

To more clearly describe the present disclosure, aspects, parts, and elements that are irrelevant to the description or known to those skilled in the art may be omitted.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of,” when preceding a list of elements, modify the entire list of elements and do not modify the individual elements of the list. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Further, throughout the specification, the phrase “in a plan view” means when an object portion is viewed from above, and the phrase “in a cross-sectional view” means when a cross-section taken by vertically cutting an object portion is viewed from the side.

The present disclosure relates a cover window and a manufacturing method thereof. Hereinafter, a cover window and a method of manufacturing the cover window according to embodiments of the present disclosure will be described, in detail, with reference to the drawings.

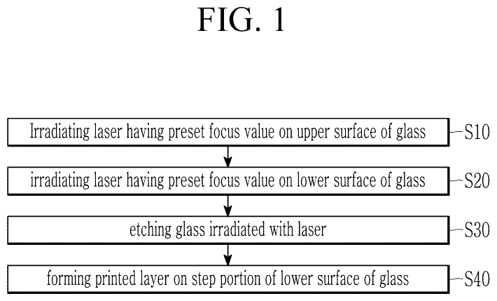

FIG. 1 is a flowchart showing steps of a method of manufacturing a cover window according to an embodiment. Referring to FIG. 1, the method of manufacturing the cover window according to an embodiment of the present embodiment includes irradiating a laser having a preset focus value on an upper surface of a glass (S10), irradiating a laser having a preset focus value on a lower surface of the glass (S20), etching the laser-irradiated glass (S30), and forming a printed layer at a step portion of the lower surface of the glass (S40).

According to a method of manufacturing the cover window according to an embodiment of the present embodiment, the cover glass having a desired curvature may be formed by irradiating the glass with a laser having a preset focus value and then etching the glass. The irradiated laser has an xyz value of its focus (e.g., a preset xyz value of its focus) and may form a hole at a target point of the glass, for example, at an area corresponding to the coordinate value of the focus by laser irradiation. A plurality of holes may be formed from (e.g., extending from) a surface of the glass to a focal point.

In addition, according to an embodiment of the manufacturing method of the cover window, a step portion may be formed by irradiating a laser on (or to) a lower portion of the glass and then etching. The printed layer may be filled in the step portion to alleviate (or prevent) a problem in which a step is generated by the printed layer. In a process of irradiating the laser to the lower portion of the glass, glass cutting may be done together, and therefore, a separate glass cutting process is not required and a process (e.g., a manufacturing process) may be simplified. In addition, because step formation and cutting of the lower portion of the glass are performed at the same time (or concurrently), a tolerance in the process may be precisely controlled.

Now, steps of the manufacturing method of the cover window according to embodiments of the present disclosure will now be described in more detail.

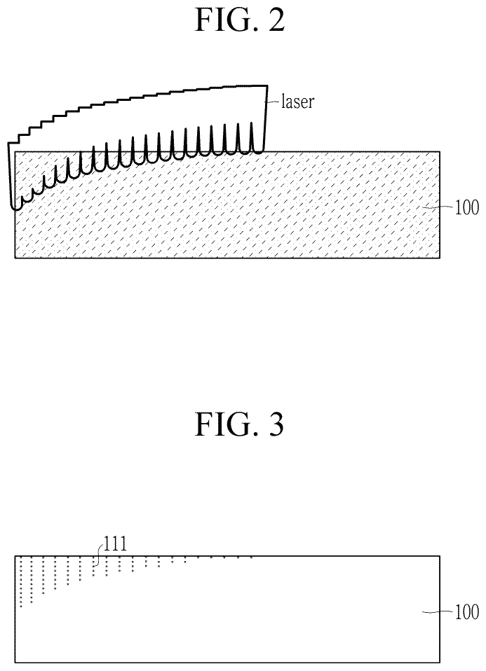

First, a laser having a focus value (e.g., a preset focus value) is irradiated onto the upper surface of the glass (e.g., a cover glass or cover window) 100 (S10). FIG. 2 schematically illustrates a process in which a laser is irradiated to an upper portion of a glass 100 in this step. As illustrated in FIG. 2, a plurality of holes (e.g., grooves or blind holes) may be formed in the glass 100 while the laser having a preset focus value is irradiated onto the glass 100. In such an embodiment, the holes formed in the glass 100 may be formed to correspond to an xyz focus position of the laser. In FIG. 2, the irradiated laser is indicated by a line, and a region through which the lines in FIG. 2 pass is a region at where the glass 100 is affected by (e.g., irradiated by) the laser.

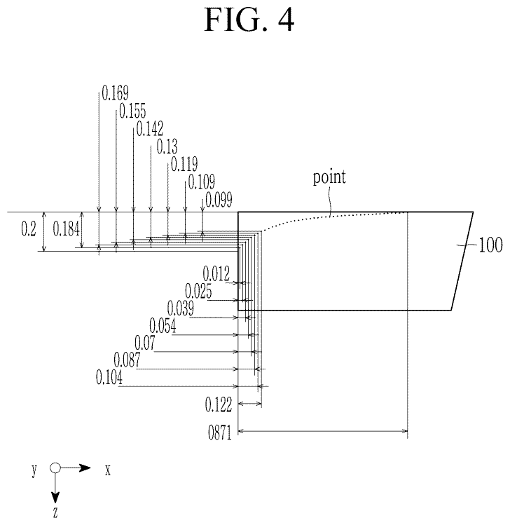

FIG. 3 illustrates a cross-section of the glass 100 of in which a hole (or holes) 111 is formed by laser irradiation. As illustrated in FIG. 3, a plurality of holes 111 formed at different positions are formed in the glass 100 by respective (or successive) laser irradiations.

The focus value of the irradiated laser may be set (e.g., may be appropriately set) depending on a desired curvature of the glass. For example, the focus value of the laser may be set depending on a curvature desired by a user. Conventionally, when wet etching is performed to form the curvature of the glass, only a naturally formed curvature could be formed. However, in the manufacturing method according to embodiments of the present disclosure, a desired curvature may be freely devised depending on setting the focal value of the laser.

Table 1 below shows a focus value of a laser according to an example. Table 1 lists only some survey points as examples. In other words, Table 1 is only an example, and the present disclosure is not limited thereto. A user may freely adjust the focus value of the laser to achieve the desired curvature.

TABLE 1

| | X | Y | Z |
|---|---|---|---|
| Point 1 | 0 | 0 | −0.2 |
| Point 2 | 0.012 | 0 | −0.184 |
| Point 3 | 0.025 | 0 | −0.169 |
| Point 4 | 0.039 | 0 | −0.155 |
| Point 5 | 0.054 | 0 | −0.142 |
| Point 6 | 0.07 | 0 | −0.13 |
| Point 7 | 0.087 | 0 | −0.119 |
| Point 8 | 0.104 | 0 | −0.109 |
| Point 9 | 0.122 | 0 | −0.099 |
| . . . | . . . | 0 | . . . |
| Point 48 | 0.871 | 0 | 0 |

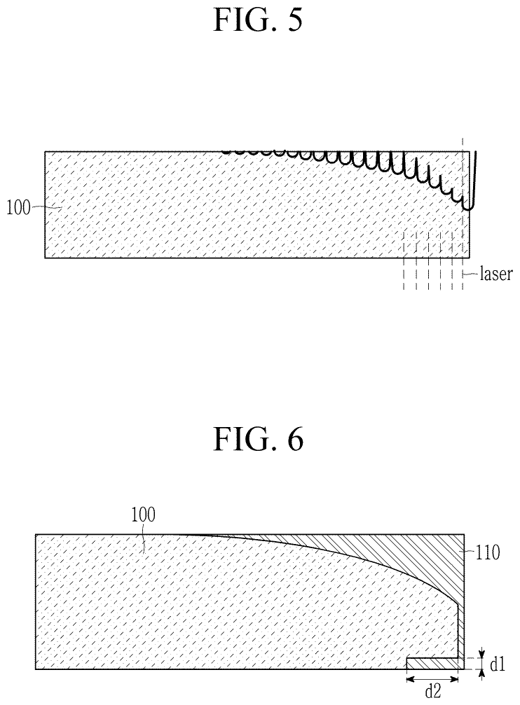

FIG. 4 illustrates a position of a laser irradiated according to coordinates in Table 1. Portions indicated by dots in FIG. 4 are irradiation points to which the laser is irradiated, respectively, and numerical values described in connection with (some of) the respective points are x-axis coordinates and z-axis coordinates of the laser irradiation points. Table 1 and FIG. 4 show irradiation points for positions where y is 0 in the glass, and even when the y-axis coordinate values are different, the x-axis and z-axis coordinates of each of the irradiation points may be the same. For example, in the embodiment of Table 1 and FIG. 4, when the y coordinate is 1, an x coordinate of Point 2 may be 0.012, and a z coordinate may be −0.184 (e.g., the y coordinates may be modified without modifying any corresponding x or z coordinate). Accordingly, glass having a uniform curved surface may be formed. In a next step, a laser having a focus value (e.g., a preset focus value) is irradiated onto a lower surface of the glass (S20). The laser irradiated to the upper surface in the previous step (S10) form the curvature of the glass, and in this step (S20), the laser irradiated to the lower surface form the step portion in the glass.

The laser irradiated in this step (S20) forms a step portion, and a z value of the irradiation point to which the laser is irradiated may be uniform. However, this is only an example, and in this step, a curved surface having a curvature may be formed on the lower surface of the glass and the step portion is formed. In addition, the step portion may not have a uniform depth (e.g., may have a non-uniform depth) and may have different depths depending on region. In such an embodiment, the z value of the irradiation point to which the laser is irradiated may be different for each irradiation point.

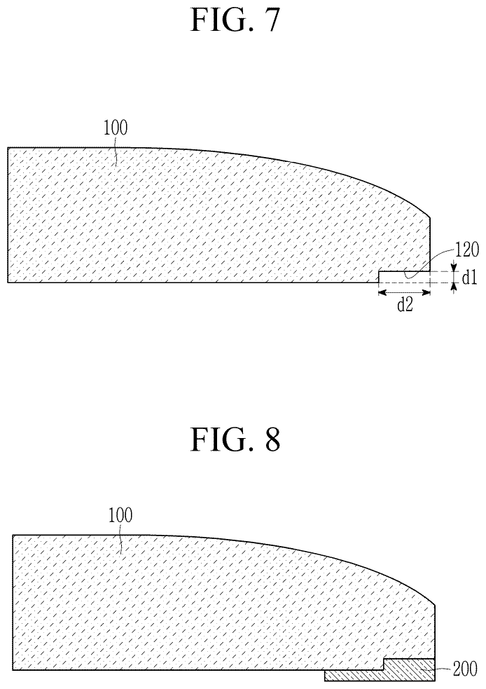

FIG. 5 schematically illustrates a process in which a laser is irradiated to a lower portion of a glass. Referring to FIG. 5, a laser may be irradiated to form a step portion under (e.g., in a lower surface of) the glass. A laser irradiation region on the upper surface of the glass from the previous step (step (S10), see, e.g., FIGS. 2 and 3) is illustrated by a dark line, and the laser irradiated to the lower surface of the glass in this step (S20) is illustrated by a dotted line.

The laser irradiated to the lower surface of the glass is used to form a step portion from which glass is removed. This step portion may be filled with a printed pattern in a subsequent step. The printed pattern, which is a layer for covering the non-display area at an edge of the display device, may correspond to a bezel portion of the display device. When the printed pattern is printed on the lower surface of the glass, a step may occur due to a thickness of the printed pattern, and the glass may be easily damaged at the step. However, according to the manufacturing method described herein, there is no step difference because a step is formed on the lower surface of the glass and the printed pattern is positioned within the step. Accordingly, damage to the glass due to the step difference may be avoided.

In step S20, a cutting line for cutting the glass may be formed (e.g., may be concurrently or simultaneously formed). For example, the laser irradiated to the lower surface of the glass may form a step portion and a cutting line. A laser irradiation line for (or acting as) a glass cutting line is illustrated in FIG. 5. It is shown in FIG. 5 that a depth of the laser irradiation line for forming the glass cutting line is greater than the laser irradiation lines for forming the step portion. For example, when the z value of the laser irradiation point in the step portion is 1, the glass cutting line may be formed by making the z value of the laser irradiation point as deep as 10 in the glass cutting line. The stated z values are, however, example values.

As such, in accordance with the manufacturing method according to an embodiment, laser irradiation for forming the step and laser irradiation for forming the glass cutting line may be performed in a single process, thereby reducing (or minimizing) a process error. For example, when the glass cutting line is formed separately from (e.g., in a different process than) the laser irradiation for step formation, a process error may occur due to misalignment between the laser and the glass in each process. However, in accordance with the manufacturing method according to an embodiment, laser irradiation for forming the step and laser irradiation for forming the glass cutting line may be performed in a single process, thereby reducing (or minimizing) the process error.

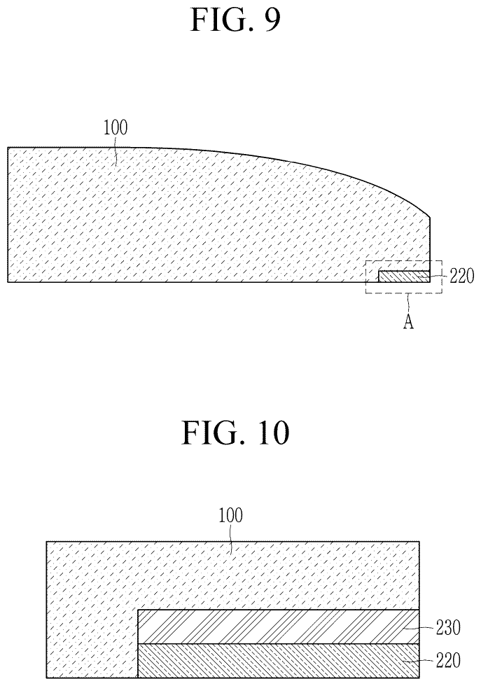

FIG. 6 separately illustrates an area subject to a laser-by-laser irradiation. A laser irradiation region 110 of the glass 100 is illustrated in FIG. 6. The laser irradiation region 110 includes a step portion and a glass cutting line. In FIG. 6, a depth d1 of the step portion may be in a range of about 1 μm to about 350 μm. In addition, a width d2 of the step portion may be in a range of about 0.1 mm to about 3 mm. However, this is only an example, and the present disclosure is not limited thereto.

FIGS. 5 and 6 illustrate a configuration in which the step portion is connected to (e.g., opens to or extends to) an edge of the glass 100, but according to an embodiment, the step portion may be spaced apart from the edge of the glass 100. Such embodiments will be described later.

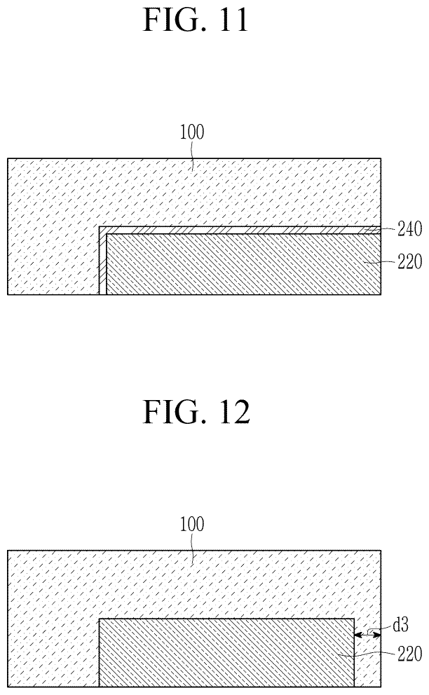

Next, the glass to which the laser is irradiated is etched (S30). The etching may be performed by a wet etching method using an etchant. The etchant may contain KOH or HF. The laser irradiation region 110 of the glass 100 shown in FIG. 6 is removed by the etching in this step. FIG. 7 shows the glass 100 after the etching. Referring to FIG. 7, the laser irradiation region 110 is removed during the etching process to form a curved surface having a curvature (e.g., a desired or designed curvature) on an upper surface of the glass 100 and a step portion 120 on the lower surface thereof. As described above, the depth d1 of the step portion 120 may be in a range of about 1 μm to about 350 μm, and the width d2 of the step portion 120 may be in a range of about 0.1 mm to about 3 mm. However, this is only an example, and the present disclosure is not limited thereto. In FIG. 7, the step portion 120 is shown as being connected to (e.g., as extending to) the edge of the glass 100, but in other embodiments, the step portion 120 may be spaced apart from the edge of the glass 100.

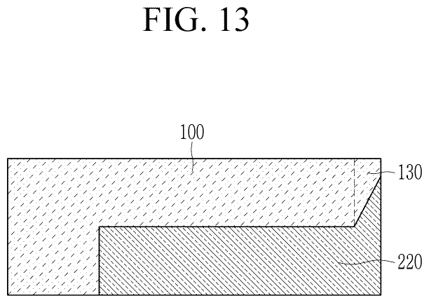

Next, a printed layer is formed on (or in) the step portion of the lower surface of the glass (S40). FIGS. 8 and 9 each illustrate a process of forming a printed layer 220. Referring to FIG. 8, a printed layer material 200 is filled in the step portion 120 by using methods, such as silk screening, inkjet printing, and pad printing. Although a configuration in which the printed layer material 200 is formed as a single layer is illustrated in FIG. 8, the printed layer material 200 may be multi-layered according to other embodiments. Various modifications will be separately described below. As shown in FIG. 8, in a process of filling the printed layer material 200, the printed layer material 200 may be formed to be thicker than the step portion 120. In addition, it may be formed around the step portion 120.

Next, referring to FIG. 9, a step (e.g., a protruding portion) of the printed layer material 200 is removed. For example, when the printed layer material 200 is formed to be thicker than the step portion 120 as illustrated in FIG. 8, the printed layer 220 may be formed by removing some of it (e.g., by removing the protruding portion). The removal of the printed layer material 200 may be performed by a method, such as chemical-mechanical polishing (CMP) or polishing. The printed layer 220 may cover the non-display area of the display device and may correspond to the bezel area. The printed layer 220 may include a black material to cover a structure, such as a wire, of the display device.

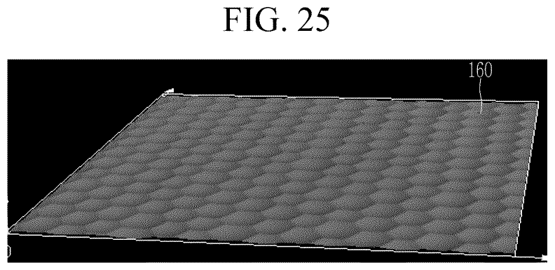

When the cover window manufactured in this way, the surface of the laser irradiation region may appear concavo-convexly. This is an irradiation trace formed by laser irradiation, and the concavo-convex surface is illustrated in FIG. 25, which will be described below. For example, in the cover window manufactured according to an embodiment of the present disclosure, a surface of the laser irradiation region, such as a curved portion and a stepped portion, may be concavo-convex.

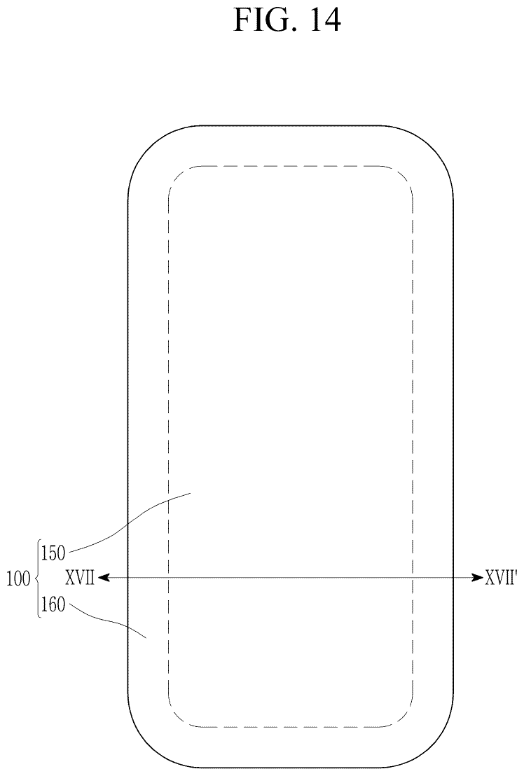

Now, various modifications will be described below. FIGS. 10 to 13 illustrate enlarged views of the portion indicated by A in FIG. 9, and the configuration and shape of the step portion 120 are different in each of FIGS. 10 to 13.

Referring to FIG. 10, a transparent layer 230 and a printed layer 220 may be sequentially stacked on a stepped portion of the glass 100. In this embodiment, the transparent layer 230 may be disposed closer to an upper surface of the cover window (e.g., the glass 100) than the printed layer 220 is.

As described above, in the manufacturing method of the cover glass according to an embodiment, a laser having a focus value (e.g., a preset focus value) is irradiated on a cover glass 100, which is then etched. The etched surface of the cover glass 100 may be concavo-convex rather than flat due to the laser irradiation process. In this way, the etched surface of the non-flat glass may not be transparent and may be viewed as cloudy. However, in the embodiment shown in FIG. 10, when the transparent layer 230 is filled in contact with the etched surface of the glass 100, the glass 100 may not appear cloudy.

Referring to FIG. 11, a metal layer 240 may be disposed along the etched surface of the step portion 120. The etched surface of the cover glass 100 is covered with the metal layer 240, and the printed layer 220 may be disposed in contact with the metal layer 240. For example, the metal layer 240 may be disposed between the printed layer 220 and the cover glass 100. The metal layer 240 may have various colors. In this embodiment, a bezel may be displayed in various colors instead of black, thereby improving a finish. An outer cover of the display device and the metal layer 240 may be made in the same color to be visually recognized as if there is no bezel.

Although the configuration in which the step portion 120 and the edge of the cover glass 100 are connected is illustrated in the previous embodiments, the step portion 120 and the edge of the cover glass 100 may be spaced apart from each other. FIG. 12 illustrates a portion of a cover window according to another embodiment. Referring to FIG. 12, the step portion 120 and the edge of the cover glass 100 are spaced apart from each other with a distance (e.g., a predetermined distance) d3 therebetween. The cover glass 100 having this shape may be formed by setting a z value of a laser irradiation point passing over a separation region to 0 during the irradiating of the laser onto the lower surface of the glass (S20). The separation distance d3 may be in a range of about 3 μm to about 5 μm, but the present disclosure is not limited thereto.

FIG. 13 illustrates a portion of a cover window according to another embodiment. Referring to FIG. 13, the cover window 100 according to the this embodiment has a chamfer portion 130 from which an edge portion is partially removed. As illustrated in FIG. 13, the chamfer portion 130 is a portion having a thin (e.g., thinner) thickness by removing a portion of the cover window 100. In an embodiment in which the cover window has the chamfer portion 130 as described above, the cover window may be more easily handled and damage thereto may be prevented. As illustrated in FIG. 13, a thickness of the cover window in the chamfer portion 130 may become thinner toward an edge thereof. Accordingly, a thickness of the printed layer 220 may increase toward the edge of the cover window.

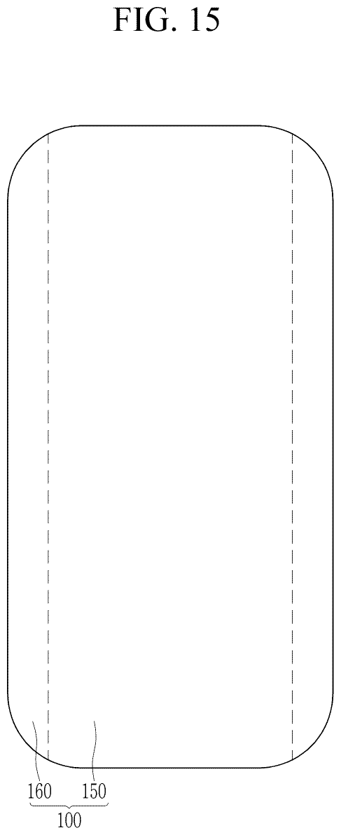

FIG. 14 illustrates a cover window manufactured according to an embodiment.

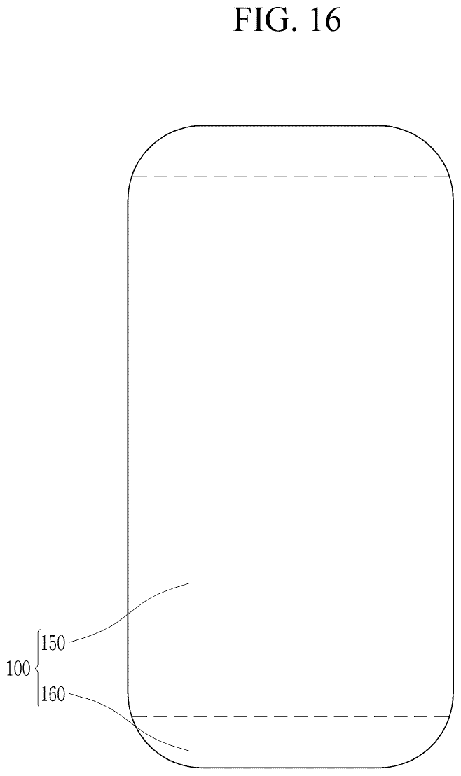

As illustrated in FIG. 14, the cover window may have a flat portion 150 and a curved portion 160. The curved portion 160 is a region irradiated with a laser and etched as described above. In FIG. 14, an embodiment in which the curved portion 160 is positioned at (e.g., extends around) all corners of the cover window 100 is illustrated, and but in other embodiments, the curved portion 160 may be positioned at only opposite corners of the cover window. For example, as illustrated in FIG. 15, the curved portions 160 may be positioned at left and right edges of the cover window 100, or the curved portion 160 may be positioned at upper and lower edges of the cover window 100 as illustrated in FIG. 16.

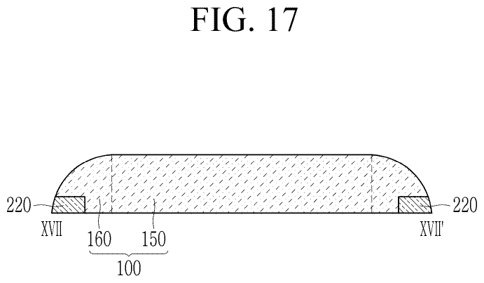

FIG. 17 illustrates a cross-sectional view of the cover window shown in FIG. 14 taken along the line XVII-XVII′. Referring to FIG. 17, because the cover window 100 is etched after irradiating a laser having a focus value, a curvature may be formed therein. Thus, a cover window may be manufactured having a curvature desired by a user rather than a curvature naturally formed during an etching process.

In addition, the step portion 120 is formed on a lower surface of the glass by laser irradiation, and the printed layer 220 is disposed within the step portion 120 to prevent a step that may otherwise be caused by formation of the printed layer 220.

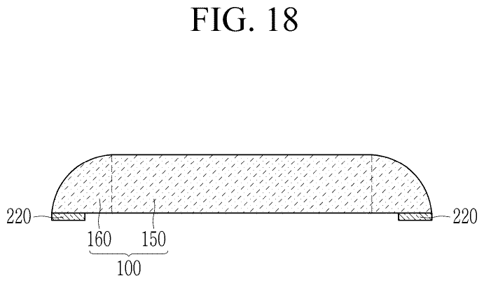

FIG. 18 illustrates a cover glass in which a step portion is not included on a lower surface of a glass. In this case, a step may occur between a region in which the printed layer 220 is formed and a region in which the printed layer 220 is not formed by formation of the printed layer 220. In this case, when an impact is applied to the cover window, damage may easily occur due to such a step difference.

However, as illustrated in FIG. 17, in the cover window according to embodiments of the present disclosure, a step difference is not present between the region in which the printed layer 220 is formed and the region in which the printed layer 220 is not formed, thereby reducing a possibility of damage to the cover window 100. In addition, laser irradiation for forming the step portion 120 and laser irradiation for individual glass cutting may be performed in a single process, thereby reducing an error due to misalignment in the process.

In the embodiment shown in FIG. 17, an upper surface of the cover window 100 as a curved surface, but according to an embodiment, both upper and lower surfaces of the cover window may have curved surfaces.

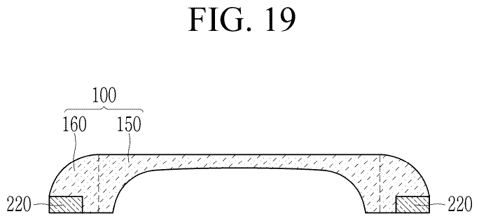

FIG. 19 illustrates a cross-section corresponding to that of FIG. 17 for a cover window according to another embodiment. Referring to FIG. 19, a curved surface having a curvature is also positioned on a lower surface of the cover window. The cover window having this shape may be formed by performing laser irradiation to form the curvature on the lower surface during a laser irradiation process for forming the step portion 120. As described above, according to embodiments of the present disclosure, a desired curvature may be formed because etching is performed after irradiating a laser having a focus value. Accordingly, as illustrated in FIG. 19, the curvatures of the upper surface and the lower surface of the cover window are manufactured to be different from each other. For example, in the cover window shown in FIG. 19, the curvature of the upper surface and the curvature of the lower surface are different from each other.

FIGS. 14 to 19 illustrate embodiments of a cover window in which the glass 100 has a flat portion 150 and a curved portion 160, but according to an embodiment, the glass may be formed entirely of only the curved portion 160.

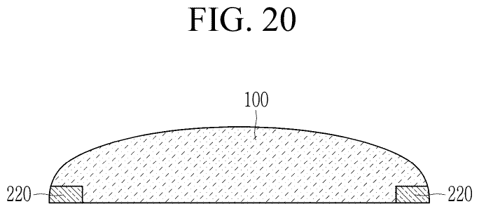

FIG. 20 illustrates a cross-section corresponding to that of FIG. 18 for another embodiment. Referring to FIG. 20, the cover window according to this embodiment is the same as that of FIG. 18 except that the cover window does not include a flat portion on an upper surface thereof and the upper surface is entirely curved. A detailed description of the same constituent elements will be omitted. In this way, when the entire upper surface of the cover window has a curved portion, it may be formed by appropriately setting a focus value in a laser irradiation step.

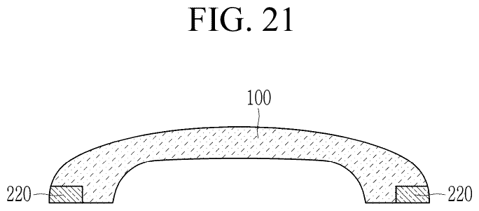

FIG. 21 illustrates a cross-section corresponding to that of FIG. 19 for another embodiment. Referring to FIG. 21, the cover window according to this embodiment is the same as that of FIG. 19 except that the cover window does not include a flat portion on an upper surface thereof and the upper surface is entirely curved. A detailed description of the same constituent elements will be omitted. In this way, when the entire upper surface of the cover window has a curved portion, it may be formed by appropriately setting a focus value in a laser irradiation step.

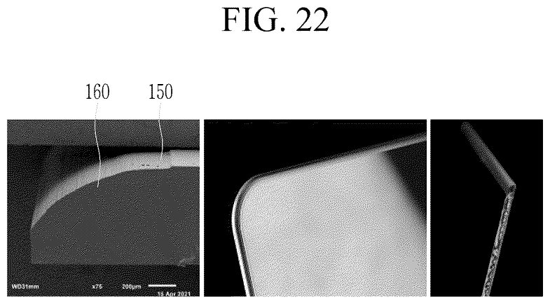

FIG. 22 is a photograph of a cover window that is manufactured according to an embodiment. As illustrated in FIG. 22, the curved portion 160 irradiated with a laser is positioned at an edge of the flat portion 150.

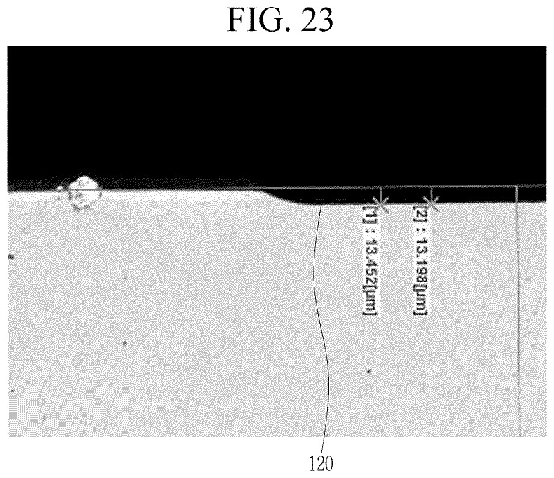

FIG. 23 is a photograph of a step portion 120 of a cover window that is manufactured according to an embodiment. As illustrated in FIG. 23, the step portion 120 was formed by laser irradiation and etching.

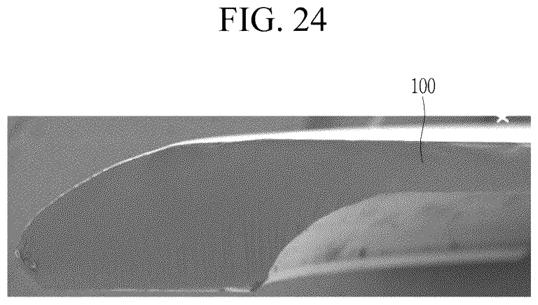

FIG. 24 is a photograph of an embodiment in which both upper and lower surfaces of a cover window have a curvature. According to embodiments of the present disclosure, a desired curvature may be formed because a laser having a focus value (e.g., a preset focus value) is irradiated and then etching is performed, and thus, curvatures of upper and lower surfaces of the cover window may be different as illustrated in FIG. 24.

An irradiation trace of the laser may remain on a surface of the glass formed by etching after laser irradiation. FIG. 25 illustrates an enlarged image showing a surface of a laser irradiation region (e.g., the curved portion 160 as described above) in a cover window manufactured according to an embodiment. As shown in FIG. 23, it was confirmed that the surface of the glass subject to laser irradiation was not uniform and a honeycomb pattern was formed by the laser irradiation.

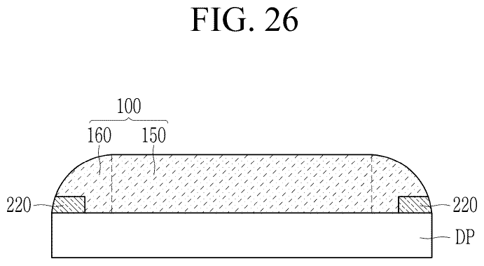

FIG. 26 schematically illustrates a display device including a cover window according to an embodiment. The cover window 100 may be positioned on the display panel DP, and the cover window 100 may be that of one of the various embodiments described above. A detailed description of the same constituent elements will be omitted. In FIG. 26, as an example, the cover window 100 according to the embodiment shown in FIG. 17 is illustrated. The cover window 100 may have a flat portion 150 and a curved portion 160, and the curved portion 160 may have a desired curvature by irradiating a laser having a focal value (e.g., a preset focal value). The step portion 120 may be formed in a lower surface of the cover window 100, and a printed layer 220 may be positioned within the step portion 120.

While the present disclosure has been described in connection with what is presently considered to be practical embodiments, it is to be understood that the present disclosure is not limited to the disclosed embodiments. On the contrary, the present disclosure is intended to cover various modifications and equivalent arrangements included within the spirit and scope of the appended claims and their equivalents.

Description of Some Reference Symbols

| | |
|---|---|
| 100: glass | 110: irradiation region |
| 111: hole | 120: step portion |
| 130: chamfer portion | 150: flat portion |
| 160: curved portion | 200: printed layer material |
| 220: printed layer | 230: transparent layer |
| 240: metal layer | |

What is claimed is:

1. A manufacturing method of a cover window, the method comprising:
irradiating a laser at a plurality of first positions on a first surface of a glass, the laser having a focus value for each of the first positions;
irradiating a laser at a plurality of second positions on a second surface of the glass, the laser having a focus value for each of the second positions;
forming a curved portion on the first surface of the glass and a step portion on the second surface of the glass by etching the irradiated first and second positions of the glass; and
forming a printed layer on the step portion in the second surface of the glass.

2. The manufacturing method of claim 1, wherein the curved portion and the step portion have a concavo-convex surface.

3. The manufacturing method of claim 1, wherein a line connecting of the second positions on the second surface of the glass has same curvature as that of the curved portion of the glass.

4. The manufacturing method of claim 1, wherein, during the irradiating of the laser at the plurality of first positions on the first surface of the glass, a hole is formed in the first surface of the glass corresponding to each of the first positions.

5. The manufacturing method of claim 4, wherein a line connecting each of the holes forms a curved surface having a curvature in the first surface of the glass.

6. The manufacturing method of claim 1, wherein, during the irradiating of the laser at the plurality of second positions on the second surface of the glass, the laser is irradiated onto a region of the second surface of the glass.

7. The manufacturing method of claim 6, wherein a depth of the region irradiated with the laser is in a range of 1 μm to 350 μm.

8. The manufacturing method of claim 6, wherein a width of the region irradiated with the laser is in a range of 0.1 mm to 3 mm.

9. The manufacturing method of claim 6, wherein, during the irradiating of the laser at the plurality of second positions on the second surface of the glass, the laser is irradiated from an edge of the glass to pass through an entire thickness of the glass.

10. The manufacturing method of claim 6, wherein the region irradiated with the laser is spaced apart from an edge of the glass.

11. The manufacturing method of claim 6, wherein the region irradiated with the laser extends to an edge of the glass.

12. The manufacturing method of claim 1, wherein the forming of the printed layer on the step portion in the second surface of the glass comprises:
filling a printed layer material in the step portion; and
planarizing the step portion filled with the printed layer material.

13. The manufacturing method of claim 1, wherein the printed layer comprises a black material.

14. The manufacturing method of claim 13, further comprising forming a transparent layer between the printed layer and the glass.

15. The manufacturing method of claim 13, further comprising forming a metal layer between the printed layer and the glass.

16. The manufacturing method of claim 12, wherein a depth of the step portion increases toward an edge of the glass, and
wherein a thickness of the printed layer increases toward the edge of the glass.

17. The manufacturing method of claim 1, wherein a curved portion of the glass is formed on the second surface of the glass.

18. The manufacturing method of claim 17, wherein a curvature of the curved portion on the first surface of the glass has a different curvature than that of the curved portion positioned on the second surface of the glass.

19. A cover window comprising:
a glass having a first surface and a second surface, a first surface of the glass having a curved portion having a certain curvature, the second surface of the glass having a step portion at where the glass is partially removed; and
a printed layer within the step portion in the second surface of the glass,
wherein the curved portion and the step portion have a concavo-convex surface.

20. The cover window of claim 19, further comprising a flat portion between curved portions at opposite edges of the glass.

21. The cover window of claim 19, further comprising a curved portion on the second surface of the glass.

22. The cover window of claim 21, wherein a curvature of the curved portion on the first surface of the glass is different from a curvature of the curved portion positioned on the second surface of the glass.

23. The cover window of claim 19, further comprising a transparent layer between the printed layer and the glass.

24. The cover window of claim 19, further comprising a metal layer between the printed layer and the glass.

25. The cover window of claim 19, wherein the step portion is spaced apart from an edge of the glass.

26. The cover window of claim 19, wherein a depth of the step portion is in a range of 1 μm to 350 μm, and
wherein a width of the step portion is in a range of 0.1 mm to 3 mm.

27. A cover window comprising:
a display panel; and
a cover window on a first surface of the display panel, the cover window comprising:
a glass having a first surface and a second surface, the first surface of the glass having a curved portion having a certain curvature, the second surface of the glass having a step portion at where the glass is partially removed; and
a printed layer within the step portion on the second surface of the glass, wherein the curved portion and the step portion have a concavo-convex surface.
